(19) United States
(12) Patent Application Publication
(10) Pub. No.: US 2008/0238519 A1
(43) Pub. Date: Oct. 2, 2008

(54) Signaling circuit and method for integrated circuit devices and systems

(76) Inventor: Ashok Kumar Kapoor, Palo Alto, CA (US)

Correspondence Address: Darryl G. Walker, Suite 235, 300 South First Street, San Jose, CA, 95113, US

(21) Appl. No.: 11/728,463

(22) Filed: Mar. 26, 2007

(51) Int. Cl. H03K 3/26; G06F 17/50

(52) U.S. Cl. 327/297; 716/6

(57) ABSTRACT

Integrate circuit systems and semiconductor devices for generating, transmitting, receiving, and manipulating clock and/or data signals. A semiconductor device including a clock circuit having field effect transistors and a clock driver circuit having bipolar junction transistors is disclosed. The clock circuit may provide a first clock output having a first voltage swing. The clock driver circuit may receive the first clock output and provide a second clock output having a second voltage swing substantially less than the first voltage swing. The field effect transistors can be junction field effect transistors or insulated gate field effect transistors, or the like. The system/devices further including a translator circuit, for translating signals with a lower voltage swing into signals with a higher voltage swing, and a circuit block, for operating at such higher voltage swing. Further included are global and local wiring networks for communicating the signals between and among the individual circuits or system components.

### TECHNICAL FIELD

The present invention relates generally to semiconductor integrated circuit devices, and more particularly to circuits and methods for transmitting, receiving and distributing signals on an integrated circuit and systems including integrated circuits.

### BACKGROUND OF THE INVENTION

Integrated circuit (IC) devices typically include a number of sections formed in one or more substrates that are electrically interconnected to one another. As operating speeds for such devices has increased, the transmission of electrical signals across ICs with predetermined timing has become source of many design concerns, including timing failures and power consumption. Timing failures can arise due to instability of power supply levels, including “voltage droop” (a drop in a high power supply level) and/or “ground bounce” (a rise in a low power supply level). Timing failures can also arise due to transmission line effects, which can generate reflections at a signal receiving end that can propagate back to a signal source.

Power consumption is an increasing concern due to the switching of signals, particularly periodic signals, such as clock signals. Lines carrying such signals are typically driven between power supply levels in conventional approaches. As operating speeds of integrated circuits have increased, so have the switching rate of such signals. As a result, timing signals, particularly clock signals, can now account for a significant portion of overall power consumption.

To better understand various features of the disclosed embodiments, a number of conventional signaling approaches will now be described.

Referring now to FIGS. 15A and 15B, a conventional IC signaling example is shown in a block schematic diagram and a timing diagram. FIG. 15A shows two signaling paths subject to unwanted crosstalk. Crosstalk can occur when signals are unintentionally coupled to one another, via a mutual capacitance between two signal lines. FIG. 15A shows a first signaling path 1500 for a clock signal CLK, and a second signaling path 1502 for a signal S1. A signal CLK can be a periodic signal that can be distributed over an integrated circuit device to ensure that operations are executed according to a predetermined timing. As such, a clock signal CLK can be active while an integrated circuit is in a normal operating mode. A signal S1 can be a signal generated during the operation of the integrated circuit. The rate at which signal S1 switches with respect to signal CLK can be much slower.

Each conventional signal path (1500 and 1502) can include a number of signal buffers 1504 interconnected by signal lines 1506 and 1508. Signal path 1500 receives signal CLK and outputs clock signal CLK_OUT. Signal path 1502 receives signal S1_IN and output signal S1_OUT.

FIG. 15B is a timing diagram showing waveforms corresponding to the two signaling paths of FIG. 15A. Waveform CLK can be clock signal CLK transmitted by signal path 1500. Waveform S1_START can be an initial output signal on signal path 1502. Waveform S1_END can be a signal from signal path 1502 at the end of signal line 1508. As shown, due to capacitive coupling, a signal line 1508 can rise or fall in synchronism with transitions in the clock signal CLK, rather than maintain one particular state (high or low). Absent the effects of a crosstalk, a signal S1_END can transition as desired (shown as “no xtalk”). However, due to crosstalk signal S1_END can have an unwanted delay (shown as “xtalk”), as a driver compensates for a dip in the power supply level.

In this way, capacitive coupling can result in unwanted signal delay. While capacitive coupling of signals, particularly periodic signals, can adversely impact signal transmission, such effects can also impact power supply stability. This is shown in the conventional example of FIGS. 16A to 16C. FIG. 16A shows an integrated circuit 1600 power supply routing. A high power supply voltage VDD can be provided via wiring 1602, while a low power supply voltage GND can be provided via wiring 1604. In this way, power supply voltages (VDD and GND) can be provided to different blocks within integrated circuit 1600. It is understood that operations within integrated circuit 1600 can be timed according to a clock signal CLK.

Referring now to FIG. 16B, a timing diagram shows a relationship between clock signals and power supply voltages for different blocks of integrated circuit 1600. FIG. 16B shows a clock signal CLK. In addition, the waveforms show high power supply voltages for two different blocks VDD(BLK1) and VDD(BLK2), as well as low power supply voltages for such different blocks GND(BLK1) and GND(BLK2). As shown in the figure, because a majority of circuit operations are activated in response to a clock signal (CLK) or its inverse (CLKB, not shown), there can be a droop (temporary drop) in a high power supply voltage level, as well as bounces (temporary rise) in low power supply voltage levels. Such deviations can be in synchronism with clock signal transitions.

Referring now to FIG. 16C, one potential impact resulting from dips in a power supply voltage is shown in a timing diagram. FIG. 16C shows two waveforms, one for a switching response SBLK1 that has been adversely affected by power supply level instability, and another switching response SBLK2 that has been minimally affected by power supply instability. As shown, because a power supply voltages can be lower (or higher) at the time a signal switches state, the resulting switching speed can be slower than an ideal response. In this way, the effects of timing signals on power supply voltage levels can adversely affect the speed at which signals switch between levels.

Referring now to FIG. 17, one very particular example of a conventional IC clock scheme is shown in a top plan view, and designated by the general reference character 1700. An IC can include a number of sections, including “core” sections 1702, (input/output) I/O sections 1704, and a clock section 1706. A clock section 1706 can receive a clock input signal CLK_EXT, and in response thereto, generate an internal clock signal CLK_IN. A clock section 1706 can include various phase shifting circuits, such as delay locked loop (DLL) or phase locked loop (PLL) type circuits, as well as buffer/pulse shaping circuits. Alternatively, a clock section 1706 can generate a clock signal with an oscillator, or the like.

To ensure proper timing, a clock signal CLK_IN can be distributed to each of the core and I/O sections (1702 and 1704). Additional clock branching and buffering can occur within the various sections (1702 and 1704). In such a conventional clock distribution network, buffers can be included to ensure a propagation delay does not exceed a predetermined maximum delay. Clock signal CLK_IN can thus be distributed over an IC 1700 by a network that includes numerous conductive lines having an inherent capacitance. In such an arrangement, as a timing signal is driven on such lines, power consumption can be consumed according to the following relationship:

PowerαCₙₑₜV²,

where Cₙₑₜ is the capacitance of the network, and V is the magnitude of the signal swing. Thus, the transmission of such a signal can consume considerable power during the operation of the integrated circuit. Further, the power consumption varies according to the square of the clock signal amplitude.

FIG. 17 shows a conventional integrated circuit that can be of the complementary metal oxide semiconductor (CMOS) type. Further, the example shown, clock circuits are assumed to be CMOS buffer type circuits, and so drive a clock signal between a low power supply voltage (e.g., ground) and a high power supply voltage VDD.

Because operations of the circuit are based on a clock signal CLK_IN, the clock signal typically has the fastest frequency of all timing signal. As a result, a clock distribution can represent a substantial portion of the overall power consumption for the IC 1700.

While the above description of FIG. 17 can include a CMOS type circuit, for additional performance, other conventional IC technologies have been employed. For example, conventional approaches have integrated bipolar transistors with CMOS transistors to form “BiCMOS” integrated circuits. Such circuits typically utilize bipolar junction transistors (BJTs) for faster switching speeds, to provide faster signal driving capabilities, or to provide I/O circuits compatible with bipolar related signaling conventions (e.g., transistor-transistor logic (TTL) or emitter-coupled logic (ECL)).

FIG. 18 is a block schematic diagram representation of a conventional clock distribution arrangement. An IC 1800 can include a clock section 1802, a clock distribution network 1804, and a number of circuit blocks 1806-0 to 1806-5. A clock section 1802 can provide a clock signal CLK to a network 1804. Network 1804 can provide a clock signal to circuit blocks (1806-0 to 1806-5). As shown, clock section 1802 and circuit blocks (1806-0 to 1806-5) can operate between voltage levels VDD and Vgnd. Thus, a clock signal CLK can vary between VDD and Vgnd. It is understood that network 1804 can include buffers and the like also operating between VDD and Vgnd.

Conventional BiCMOS may provide circuits that can still consume considerable power, as they can drive voltages between VDD and V_{BE}, where V_{BE} is the base-emitter bias. Thus, such approaches can consume power according to the relationship: Power α Cₙₑₜ(V−V_{BE})², which can still be a considerable power supply draw. In addition, conventional BiCMOS devices have not scaled to the lower power supply voltages included in advanced CMOS devices.

### BRIEF DESCRIPTION OF THE DRAWINGS

FIG. 1A is a block schematic diagram of an integrated circuit device according to one embodiment.

FIG. 1B is a block schematic diagram of a system according to another embodiment.

FIG. 1C is a block schematic diagram of a system according to yet another embodiment.

FIGS. 2A and 2B are block schematic diagrams of signal paths according to two more embodiments.

FIGS. 3A and 3B are schematic diagrams of field effect transistor (FET) buffers that can be included in the embodiments.

FIGS. 4A to 4F are schematic diagrams emitter coupled logic (ECL) type circuits that can be included in the embodiments.

FIG. 5A is a table showing power consumption differences between conventional signal driving arrangements and that according to one embodiment.

FIG. 5B is a timing diagram showing current switching differences between conventional signal driving arrangements and that according to one embodiment.

FIG. 6 is a timing diagram showing one example of signals levels according to an embodiment.

FIGS. 7A to 8C are various views showing a device structure that can be included in the embodiments.

FIG. 9 is a top plan view showing an interconnection of device structures according to one embodiment.

FIG. 10A is a diagram showing a system and method according to an embodiment.

FIG. 10B is a diagram showing a timing model according to one embodiment.

FIG. 11 is a diagram showing another system and method according to an embodiment.

FIG. 12 is a diagram showing a clock tree according to an embodiment.

FIG. 13 is a diagram showing an integrated circuit design according to an embodiment.

FIG. 14 is a timing diagram showing improvements in signal transmission according to an embodiment.

FIG. 15A is a block schematic diagram showing conventional signaling paths.

FIG. 15B is a timing diagram showing the operation of the signaling paths of FIG. 15A.

FIG. 16A is a diagram showing a conventional clock distribution network.

FIG. 16B is a timing diagram showing a relationship between clock signals and a power supply voltage in a conventional arrangement.

FIG. 16C is a timing diagram showing the effect clock signals on slower frequency signals in a conventional arrangement.

FIG. 17 is a top plan view of a conventional integrated circuit (IC) clock scheme.

FIG. 18 a block schematic diagram of a conventional clock distribution arrangement.

### DETAILED DESCRIPTION OF THE EMBODIMENTS

Various embodiments of the present invention will now be described in detail with reference to a number of drawings. The embodiments show structures, designs, and methods for an integrated circuit (IC) device that can consume less power and/or interfere less with other signals in the same IC device than conventional approaches, like those of complementary metal oxide semiconductor (CMOS) type ICs. Various embodiments can include bipolar transistors formed in the same integrated circuit as other transistors types, preferably in the same substrate as field effect transistors (FETs).

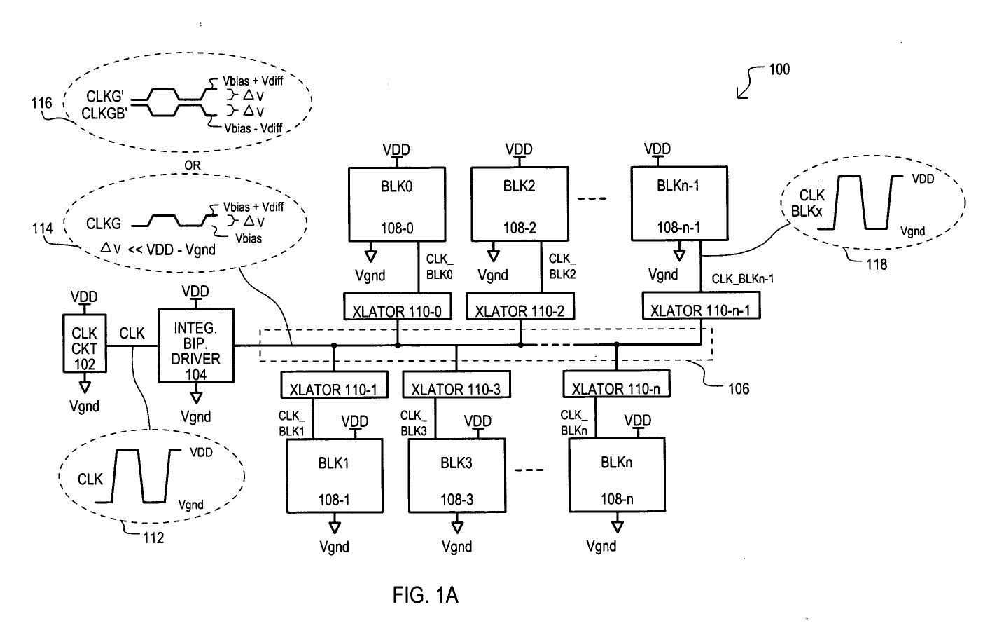

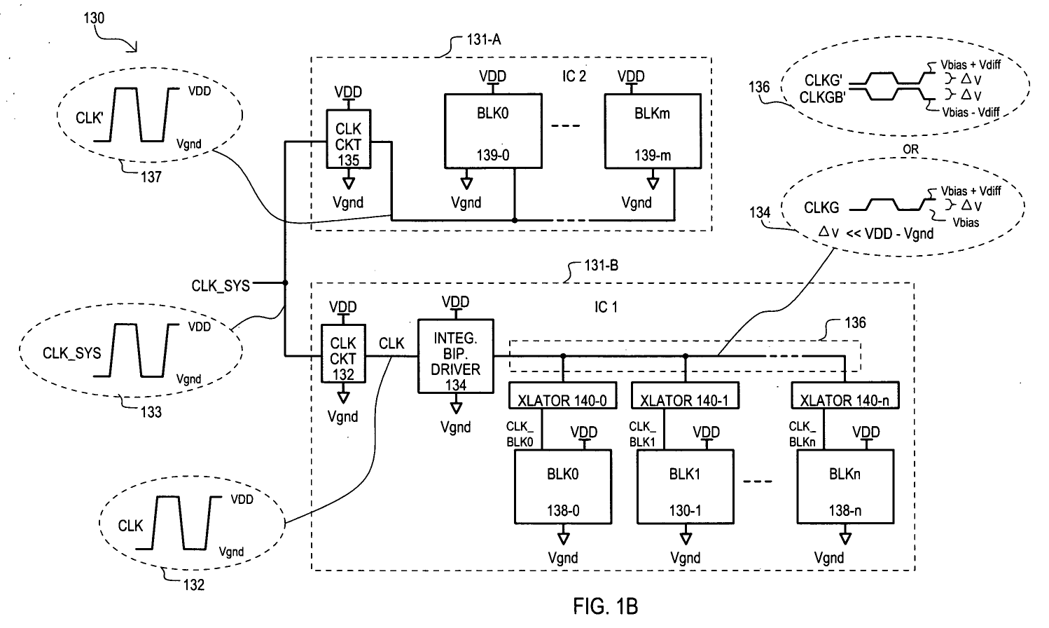

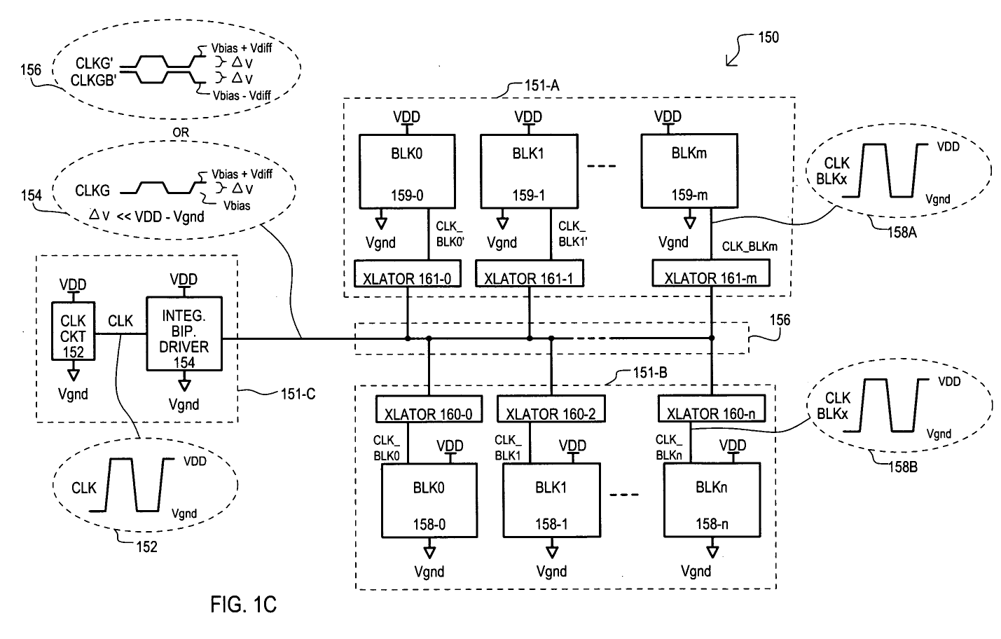

Referring now to FIG. 1A, an IC according to a first embodiment is shown in a block schematic diagram, and designated by the general reference character 100. An IC 100 can include a signal source circuit 102, a global transmitter circuit 104, a global wiring network 106, and a number of circuit blocks 108-0 to 108-n. Each circuit block (108-0 to 108-n) can be connected to global wiring network 106 by corresponding translator circuits 110-0 to 110-n.

A signal source circuit 102 can generate an initial signal CLK. A signal source circuit 102 can operate between a high power supply voltage and a low power supply voltage, in this example, shown as VDD and Vgnd, respectively. Further, in the particular example shown, an initial signal CLK can be a signal having a voltage swing between a high power supply voltage VDD and low power supply voltage Vgnd. This is shown by example in waveform illustration 112.

A signal source circuit 102 can preferably be a clock input circuit that receives a timing signal originating from a source external to the IC 100. In such an arrangement, a signal source circuit 102 can be a buffer circuit. In particular arrangements, such a buffer circuit can include phase adjustment circuits, such a phase lock loop or delay lock loop type circuits, as well as frequency multipliers and/or dividers. However, in alternate embodiments, a timing source circuit 102 can self-generate an initial signal CLK. In such arrangements, a signal source circuit 102 can include an oscillator, as but one example.

Preferably, an initial signal CLK is a periodic signal active during normal operations of IC 100. Further, a signal source circuit 102 can have active circuit elements that can include field effect transistors (FETs), such as junction FETs (JFETs), insulated gate FETs (IGFETs), or some combination thereof.

A global transmitter circuit 104 can receive initial signal CLK, and in response thereto, generate one or more global signals CLKG. Two possible global signaling examples are shown in FIG. 1A: single ended signaling and differential signaling. Signal ended signaling is shown by waveform 114, and can include a signal that varies between a bias voltage Vbias and some offset from the bias voltage. In example shown, the offset is positive (e.g., Vbias+Vdiff). However, in alternate arrangements such an offset can be negative. A difference between global timing signal levels is shown as ΔV. Differential signaling is shown by waveform 116, and can include a first signal that varies between a bias voltage Vbias and a positive offset (e.g., Vbias+Vdiff), and a second signal the varies between bias voltage Vbias and a negative offset (e.g., Vbias−Vdiff).

A global wiring network 106 can include wiring structures for transmitting global signals (i.e., CLKG or CLKG′/CLKGB′) from global transmitter circuit 104 to translator circuits (110-0 to 110-n). For example, in arrangements having single ended signaling, a global wiring network 106 can include single wirings routes while differential signaling can include dual wiring routes. Further, a global wiring network 106 can include one or more repeaters.

Circuit blocks 108-0 to 108-n can be circuits that operate in response to local signals CLK_BLK0 to CLK_BLKn. In example of FIG. 1A, each circuit block (108-0 to 108-n) can operate between a high power supply voltage (VDD) and a low power supply voltage (Vgnd). In addition, each timing signal (CLK_BLK0 to CLK_BLKn) can be a signal having a voltage swing greater than that of a global timing signal (i.e., greater than ΔV). Preferably, local signals (CLK_BLK0 to CLK_BLKn) can vary between high power supply voltage VDD and low power supply voltage Vgnd. This is shown by example in waveform illustration 118.

Preferably, local signals (CLK_BLK0 to CLK_BLKn) can be periodic timing signals active during normal operations of IC 100. Further, any or all of circuit blocks (108-0 to 108-n) can have active circuit elements that include only, or substantially only, JFETs, IGFETs or some combination.

In one very particular arrangement, circuit blocks 108-0 to 108-n can be circuits formed with complementary IGFETs (e.g., CMOS), while a high power supply voltage VDD can be about 1.0 volts, and a low power supply voltage can be about 0 volts. At the same time, a global transmitter circuit 104 can be an ECL type circuit, and ΔV can be about 0.1 V. Such a significant reduction in signal voltage can reduce capacitive coupling effects between a global signal(s) (e.g., CLKG or CLKG′/CLKGB′) and lower frequency signals, such a logic signals generated within a circuit block (108-0 to 108-n).

In another very particular arrangement, circuit blocks 108-0 to 108-n can be circuits formed with complementary JFETs, while a high power supply voltage VDD can be about 0.5 volts, and a low power supply voltage can be about 0 volts. A global transmitter circuit 104 can provide a ΔV of about 0.1 V. This too, can provide a significant reduction in capacitive coupling effects between a global signal (e.g., CLKG or CLKG′/CLKGB′) and lower frequency signals, such a logic signals generated within a circuit block.

Each translator circuit (110-0 to 110-n) can receive a single or differential global timing signal (Vbias+Vdiff and/or Vbias−Vdiff), and in response thereto, generate a local timing signal CLK_BLK0 to CLK_BLKn for a corresponding circuit block (108-0 to 108-n). Local timing signals (CLK_BLK0 to CLK_BLKn) can vary between a high power supply voltage VDD and a low power supply voltage Vgnd.

As will be shown in more detail below, reductions in global signal voltage swing can result in substantial reductions in power consumption as compared to conventional approaches having a signal that swings between power supply voltages (i.e., rail-to-rail).

In this way, an integrated circuit device can have a global signal network that provides a signal to multiple sections having a lower voltage swing than signals within each of such sections.

While embodiments can include inter-chip signaling (signaling within one integrated circuit), alternate embodiments can include systems in which signaling occurs between integrated circuits. Two of the many possible examples of such systems are shown in FIGS. 1B and 1C.

Referring now to FIG. 1B, a system 130 according to one embodiment is shown in a block schematic diagram. A system 130 can include multiple integrated circuits, where one or more integrated circuits have high voltage swing signals, while one or more other integrated circuits have low voltage swing signals.

In the particular example of FIG. 1B, a system 130 can receive or generate a system clock signal CLK_SYS. A system clock signal CLK_SYS can be a signal having a voltage swing between a high power supply voltage VDD and low power supply voltage Vgnd. This is shown by example in waveform illustration 133.

A system 130 can include an integrated circuit 131-A that includes a clock circuit 135 that receives a system clock CLK_SYS and generates an internal clock signal CLK′. Internal clock signal CLK′ can be a signal having a voltage swing between a high power supply voltage VDD and low power supply voltage Vgnd. This is shown by example in waveform illustration 137.

A system 130 can further include an integrated circuit 131-B having the same general structure as that shown in FIG. 1A.

In this way, a system can receive a high swing voltage signal that is provided to an integrated circuit operating at such high swing levels, as well as another integrated circuit operating at lower voltage swing levels.

Referring now to FIG. 1C, a system 150 according to another embodiment is shown in a block schematic diagram. A system 150 can also include multiple integrated circuits. However, in the arrangement of FIG. 1C, a signal transmitted between integrated circuits 151-A and 151-B can be a low voltage swing signal, or signals.

Inter-chip low voltage swing signals (CLKG or CLKG′/CLKGB′) can be generated by a clock section 151-C. A clock section 151-C can be separate from, or be a portion of either of integrated circuits 151-A or 151-B.

In this way, a system can include low voltage swing signals between integrated circuits.

Having described a signaling arrangement for an integrated circuit device, particular signaling arrangements will now be described in more detail.

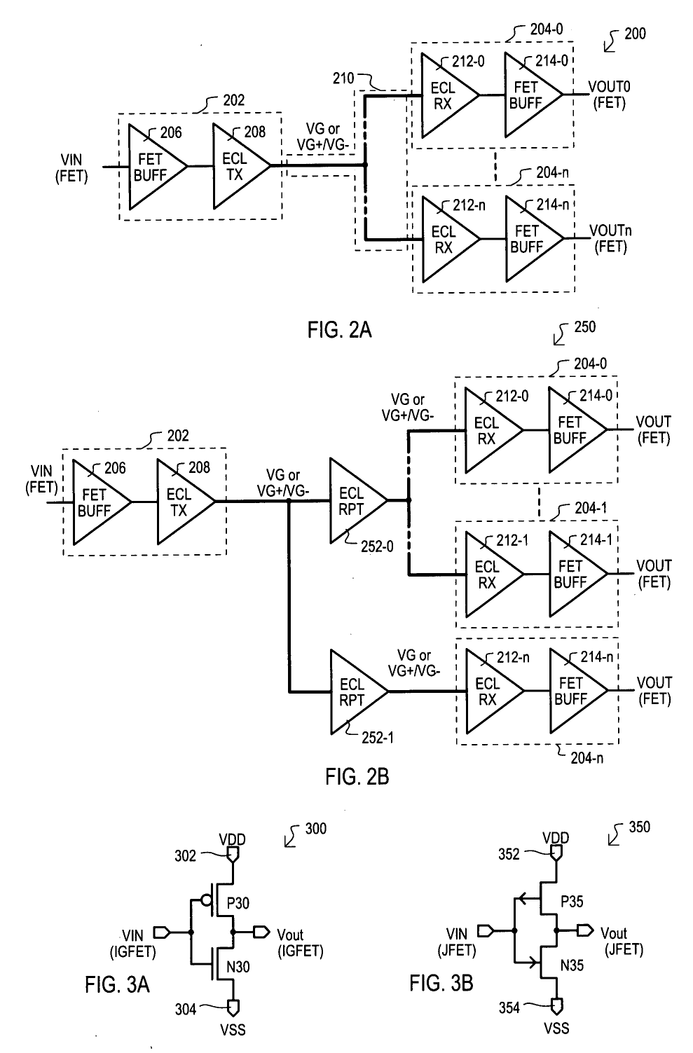

Referring now to FIG. 2A, a signal path according to one embodiment is shown in a block schematic diagram, and designated by the general reference character 200. A signal path 200 can be formed on an integrated circuit can include a global signal transmitter 202 and a number of translator circuits 204-0 to 204-n. A signal transmitter 202 can include a FET buffer 206 and a low voltage (LV) transmission buffer 208. A FET buffer 206 can receive an input signal VIN that can have a FET buffer signal level. For example, a FET buffer 206 can receive a signal that varies between a high and low power supply level, and in response thereto, output a signal that varies at the same level. A LV transmission buffer 208 can receive the output signal from the FET buffer 206, and output a signal VG having a swing that is substantially less than that of VIN. In one example, a swing of signal VG can be no more than ⅕ that of signal VIN. Alternatively, a FET buffer 206 can output a differential signal pair VG+/VG−, each of which can have a swing that is substantially less than that of VIN, and in one example no more than ⅕ that of signal VIN.

Referring still to FIG. 2A, a LV transmission buffer 208 can have an output connected to a global wiring 210. A global wiring 210 can provide a low voltage swing signal VG (or differential signals VG−/VG+), to translator circuits (204-0 to 204-n).

In the particular example of FIG. 2A, each translator circuit (204-0 to 204-n) can include a LV receiver buffer (212-0 to 212-n) and a local FET buffer (214-0 to 214-n). A LV receiver buffer (212-0 to 212-n) can receive a low voltage swing signal VG (or differential signals VG−/VG+), and in response thereto, output a signal at the VIN level. A local FET buffer (214-0 to 214-n) can operate in the same general fashion as FET buffer 206, receiving a large swing signal (with respect to VG/VG−/VG+), and outputting a signal at the same level.

In this way, a signal path can receive an input signal having a large signal swing, such as a swing between power supply levels, and provide one or more output signals at the same level at remote locations of an IC. However, transmission between a signal source and the remote locations can be by way of a small swing signal, or differential pair of small swing signals.

Referring now to FIG. 2B, a signal path according to another embodiment is shown in a block schematic diagram, and designated by the general reference character 250. A signal path 250 can include some of the same general structures as that of FIG. 2A, thus like structures are referred to by the same reference characters. Signal path 250 can differ from that of FIG. 2A in that it can include LV signal repeaters 252-0 and 252-1. A LV signal repeater (252-0 and 252-1) can be included in the event a global signal transmitter 202 lacks the drive strength for a given wiring. A LV receiver buffer (212-0 to 212-n) can receive a low voltage swing signal VG (or differential signals VG−/VG+), and in response thereto, output a signal at such a low swing level.

In this way, a signal path can receive an input signal having a large signal swing and provide one or more output signals at the same level at remote locations of an IC. However, transmission between a signal source and the remote locations can be by repeaters circuits operating at a small voltage swing.

Examples of FET buffer circuits that can be used in the various embodiments will now be described.

Referring now to FIG. 3A, a FET buffer circuit according to one embodiment 300 is shown in a schematic diagram. FET buffer circuit 300 can be a conventional complementary IGFET buffer (e.g., CMOS type buffer) that includes a p-channel IGFET P30 and an n-channel IGFET N30 with source-drain paths in series between a high power supply node 302 and a low power supply node 304. Voltage swings for input signal VIN(IGFET) and resulting output signal Vout(IGFET) can be essentially the power supply levels, which in one particular example can be between about 0 volts and 1.0 volt (i.e., about a 1.0 volt swing).

FIG. 3B shows a FET buffer circuit according to another embodiment. The FET buffer circuit 350 of FIG. 3B can be a complementary junction FET buffer that includes a p-channel JFET P35 and an n-channel JFET N35 with source-drain paths in series between a high power supply node 352 and a low power supply node 354. JFETs P35 and/or N35 can operate in an enhancement mode type operation, allowing for high impedance states when turned off. In more particular examples, JFETs P35 and/or N35 can include “back” gates in addition to front gates for greater control over channel conductivity. A JFET buffer circuit 350 operates at potentials below the p-n junction forward bias voltage for the material employed. In one particular case, JFET buffer circuit 350 can be fabricated in silicon, and thus operate below 0.7 volts, preferably at about 0.5 volts. As in the case of the IGFET buffer, voltage swings for input signal VIN(JFET) and resulting output signal Vout(JFET) can be essentially transitions between the power supply levels, which in one particular example can be between about 0 volts and 0.5 volt (i.e., about a 0.5 volt swing).

In this way, buffer circuits can provide output signals having an essentially rail-to-rail voltage swing for subsequent translation into smaller signal swing levels.

As understood from above, high voltage swing FET buffer circuits can operate in conjunction with low voltage swing LV circuits. Such LV circuits can perform various functions including (1) translate a relatively high voltage swing signal (e.g., greater than about 0.5 volts) into a low voltage swing signal (e.g., about 0.1 volts); (2) receive a low voltage swing signal and output the same (e.g., a repeater); (3) translate a low voltage swing signal into a high voltage swing signal. Very particular examples of such circuits will now be described.

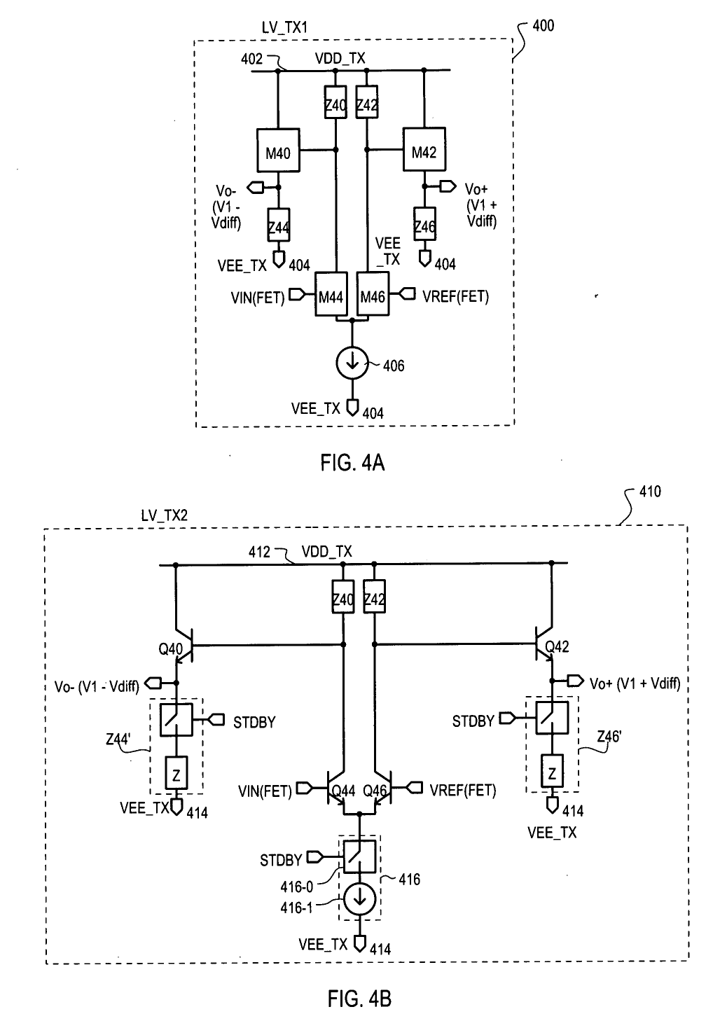

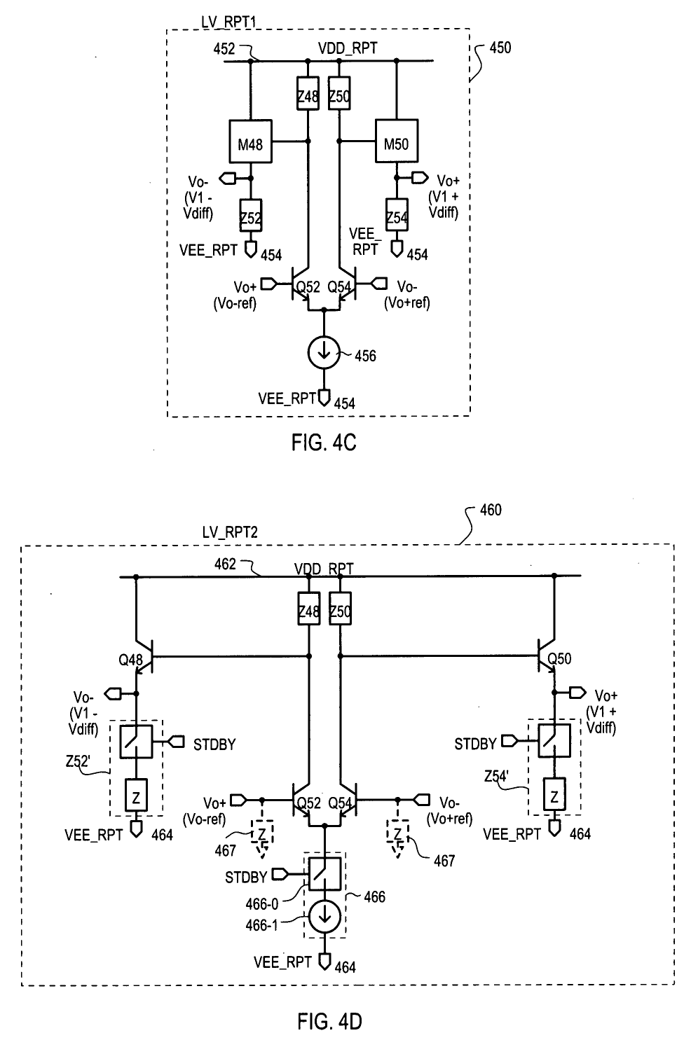

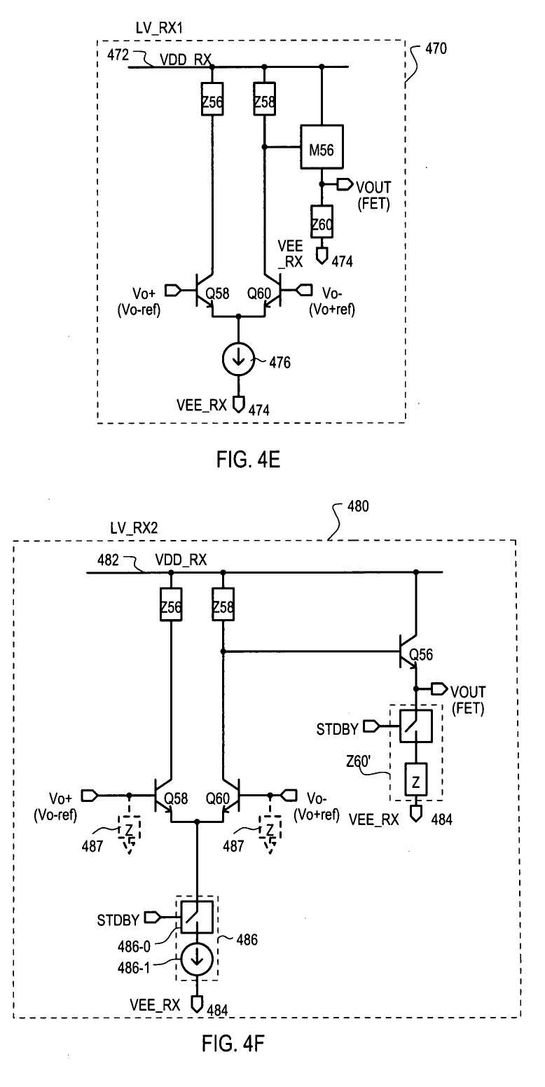

Referring now to FIG. 4A, one example of a LV transmission (TX) buffer, like that shown as 208 in FIGS. 2A/B is shown in a schematic diagram, and designated by the general reference character 400. ECL TX buffer 400 can be connected between a high power supply voltage node 402 and a second low voltage node 404, and can include a differential pair of transistors (BJTs) M44/M46, one or more driver transistors M40 and/or M42, and a current source 406.

Differential pair transistor M44 can have a control terminal that receives a high swing input signal VIN(FET), and a controllable impedance path connected to between a current source 406 and an impedance Z40. Transistor M46 has a control terminal that receives a high swing reference signal VREF(FET), and a controllable impedance path connected between to a current source 406 and an impedance Z42. Current source 406 can be connected between the current paths of transistors M44/M46 and a second low power supply node 404.

A LV TX buffer 400 can be configured to output a single ended signal (Vo− or Vo+), or a differential signal (Vo− and Vo+). In a single ended configuration, only one driver transistor M40 or M42 can be included depending upon which signal is output. In the differential configuration, both driver transistors M40/M42 can be included. If included, transistor M40 can have a control terminal connected to transistor M44, and a controllable impedance path connected between a high power supply node 402 and a second low power supply node 404 via an impedance Z44. Transistor M40 can provide a signal Vo−. Signal Vo− can vary between a potential V1 and V1−Vdiff.

If included, transistor M42 can include a control terminal connected to transistor M46, and a controllable impedance path connected between a high power supply node 402 and second low power supply node 404 via an impedance Z46. Transistor M42 can provide a signal Vo+. Signal Vo+ can vary between a potential V1 and V1+Vdiff. It is understood that if LV TX driver 400 has a differential configuration, signals Vo− and Vo+ can be essentially synchronous. That is, when signal Vo− transitions from V1 to V1−Vdiff, signal Vo+can transition from V1 to V1+Vdiif.

Any of power supply levels VDD_TXX, VEE_TX, impedance values Z40/Z42 and Z44/46, as well as current mirror 406 can be selected to set output voltage signal V1 and value Vdiff. In one particular arrangement, Vdiff can be no more than 200 mV, preferably about 100 mV. Input signal VIN(FET) can be a high voltage swing signal as described above (e.g., 1.0 volts or 0.5 volts). A reference voltage VREF(FET) can be at some level between the range of signal VIN(FET) (e.g., 0.5 volts, or 0.25 volts).

In this way, a LV TX buffer can translate a high voltage swing signal into a low voltage swing signal. A low voltage swing can be a single signal (e.g., Vo− or Vo+), or a differential pair (e.g., Vo−/Vo+).

Referring now to FIG. 4B, a more detailed example of a LV TX driver is shown in a schematic diagram and designated by the general reference character 410. LV TX driver 410 can differ from that of FIG. 4A in that driver transistors can be bipolar junction transistors Q40 and Q42. In addition, a current source 416 can be programmed into a low, or no current drawing state. In the very particular example, shown, a current source can include a current source circuit 416-1 and a control switch 416-0. In response to a signal STDBY, control switch 416-1 can be placed into a very high impedance state. In addition or alternatively, load impedances Z44′ and Z46′ can be programmable into low, or no current drawing states. In the very particular example of FIG. 4B, programmable impedances Z44′ and Z46′ can include a control switch that is enabled or disabled in response to a signal STDBY. In this way, a LV TX driver can be switched into a low current state.

The arrangement of FIG. 4B can be understood to be an emitter-coupled logic (ECL) type circuit.

Referring now to FIG. 4C, one example of a LV signal repeater, like that shown as 252-0/1 in FIGS. 2A/B is show in a schematic diagram, and designated by the general reference character 450. LV signal repeater 450 can have the same general construction as LV TX buffer shown in FIG. 4A. However, impedance values Z48, Z50, Z52, Z54 and current source 456 can be selected to provide a different operating point. More particularly, an LV signal repeater 450 can receive a low swing voltage signal (or pair of signals), and output a low voltage swing signal (or pair of signals). LV signal repeater 456 can include BJT devices Q52 and Q54 as a differential pair of input transistors. BJT devices (Q52 and Q54) can provide a high transconductance for detecting low voltage signal levels.

As in the case of LV TX buffer 400, a LV signal repeater 450 can have a single ended or differential configuration, both at an input or output. Thus, a LV signal repeater 450 can include one of transistors M48 or M50 configured for a single ended output (output only Vo−or Vo+), or both if configured for a differential output (Vo− and Vo+).

In this way, a LV signal repeater can translate a low voltage swing signal into another low voltage swing signal. A low voltage swing can be a single signal (Vo− or Vo+), or a differential pair (Vo−/Vo+).

Referring now to FIG. 4D, a more detailed example of a LV signal repeater is shown in a schematic diagram and designated by the general reference character 460. LV signal repeater 460 can differ from that of FIG. 4C in that driver transistors can be bipolar junction transistors Q48 and Q50. In addition, a current source 416, load Z52′ and/or load Z54′ can be switched off to provide a low, or no current draw state.

FIG. 4D can optionally include termination impedances 467 at one or both inputs. Termination impedances 467 can be selected to match an effective transmission line impedance presented by a conductive line carrying a signal to an input of LV TX driver 460.

The arrangement of FIG. 4D can also be understood to be an ECL type circuit.

Referring now to FIG. 4E, one example of a LV receiver (RX) buffer, like that shown as 212-(0 to n) in FIGS. 2A/B, is show in a schematic diagram and designated by the general reference character 470. ECL RX buffer 470 can have the same general construction as LV signal repeater shown in FIG. 4C. However, impedance values Z56, Z58, Z60, and current source 476 can be selected to provide a different operating point. More particularly, an LV RX buffer 470 can receive a low swing voltage signal (or pair of signals), and output a high voltage swing signal.

As in the case of LV signal repeater 450, a LV TX buffer 470 can have a single ended or differential input configuration. That is, an LV TX buffer 470 can receive a low voltage signal Vo− or Vo+, or both as inputs. LV TX buffer 470 can have a single ended output, biased to generate an output signal having a high voltage swing VOUT(FET). In one particular arrangement, a signal VOUT(FET) can have a voltage swing of about 1.0 volts or 0.5 volts.

In this way, a LV TX buffer can translate a low voltage swing signal into a high voltage swing signal. A low voltage swing can be a single signal (Vo− or Vo+), or a differential pair of signals (Vo−/Vo+).

Referring now to FIG. 4F, a more detailed example of a LV TX buffer is shown in a schematic diagram and designated by the general reference character 480. LV TX buffer 480 can differ from that of FIG. 4E in that a driver transistor can be bipolar junction transistors Q56. In addition, a current source 486 and/or impedance Z60′ can be switched off to provide a low, or no current draw state. LV TX buffer 480 can also include termination impedance 487 at one or both inputs of the buffer.

The arrangement of FIG. 4F is yet another example of an ECL type circuit.

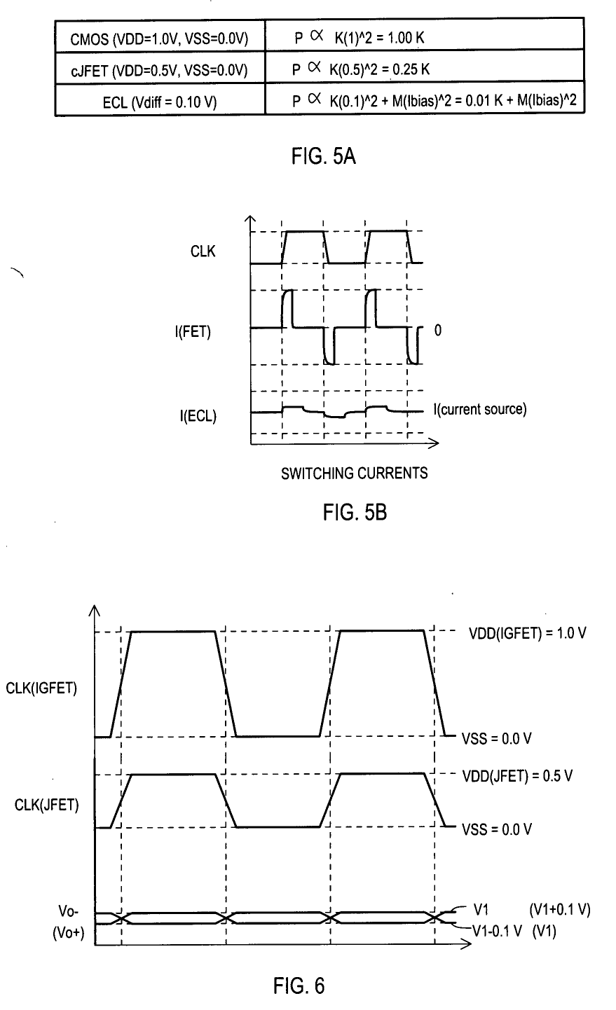

As noted above, providing for low swing voltage signals over longer signal transmission lengths of an integrated circuit device can provide power savings over conventional approaches. FIG. 5A shows a table illustrating very particular examples of power savings that can be achieved. The table of FIG. 5A includes a first row corresponding to a CMOS signal level that can vary between 0 volts and 1.0 volts. In such an arrangement, power consumption can be proportional to 1.00 K (where K is a constant). A second row shows a signal corresponding to a complementary JFET (cJFET) signal level that can vary between 0 and 0.5 volts. In this approach, as compared to the CMOS case, power consumption can ¼ that of the CMOS case. However, a last row of the table of FIG. 5A shows signals transmitted according to one embodiment. Such signals can have a swing of about 0.1 volts and include a static current draw component Ibias and some resistance constant M. This can result in power consumption a little over 1/100 that of the CMOS case.

In this way, signal transmission according to the various embodiments can provide substantial reduction in power consumption over conventional approaches.

In addition to improvements in power consumption, utilizing low voltage buffered global signaling arrangements like those described above can have advantageous current switching characteristics. Such advantages are represented in FIG. 5B.

FIG. 5B is a timing diagram showing a signal switching voltage waveform CLK, a FET buffer current switching waveform I(FET), and a low voltage (in this example an ECL) buffer current switching waveform I(ECL). Waveform CLK can represent a signal utilized to control switching. In particular, such a signal can be the input signal for a buffer circuit. Waveform I(FET) shows how a current may be drawn in a FET type buffer. Such a waveform shows that a great deal of current can be drawn as the device drives an output from one supply voltage level (e.g., 0 volts) to another (e.g., VDD of 1.0 volts or 0.5 volts). It noted that FET buffers may also have considerable leakage current (not shown) at smaller geometries.

In contrast to the waveform I(FET), the waveform I(ECL) shows an essentially constant current draw, based upon a biasing current source of the ECL circuit (e.g., like that shown as 406, 456 and 476 in FIGS. 4A to 4C). Thus, ECL buffers may have a far smaller current draw at the switching point of a transmitted signal, and a far more constant current draw over time.

It is noted that for consistently switching operations, like those for a timing clock and the like, ECL buffering can present an overall smaller current draw than FET type buffers.

In this way, a global signaling arrangement can provide a more constant and/or smaller current draw, particularly for regular switching signals, such as clock signals.

Referring now to FIG. 6, a timing diagram shows signal levels according to one very particular embodiment. FIG. 6 shows a first high voltage signal CLK(IGFET), a second high voltage signal CLK(JFET), a first low voltage signal Vo+, and a second low voltage signal Vo−. Signal CLK(IGFET) can represent a CMOS signal level that varies between 0 V and 1.0 V. Signal CLK(JFET) can represent a JFET signal level that varies between 0 V and 0.5 V. Signals Vo+ and Vo− can represent signals output by low voltage buffers or repeaters. In a single ended arrangement, one such signal can be used (Vo− or Vo+). In a differential arrangement, both signals Vo− and Vo+ can be used together.

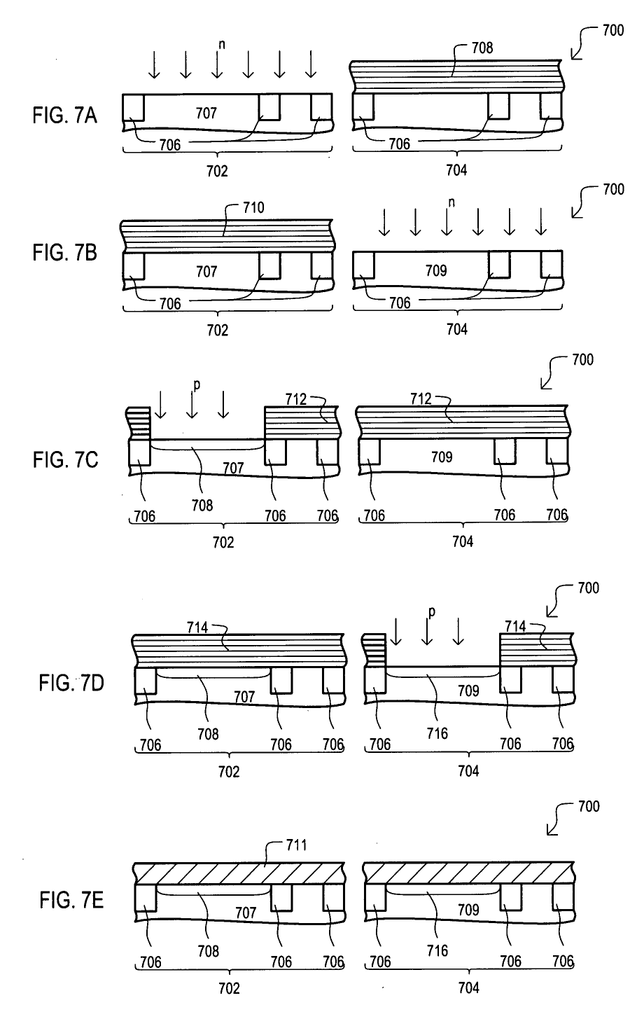

While the above embodiments have shown arrangements in which bipolar junction transistor (BJT) buffer circuits can be utilized in conjunction with IGFET type circuits, it can be particularly advantageous to incorporate such BJT circuits into complementary JFET circuits. One such approach is shown in FIGS. 7A to 7C which show various views of a device structure that can serve as either a JFET or a BJT device. Thus, an integrated circuit manufacturing process that fabricates JFET devices can easily incorporate such BJT devices to form ECL buffers circuits and the like.

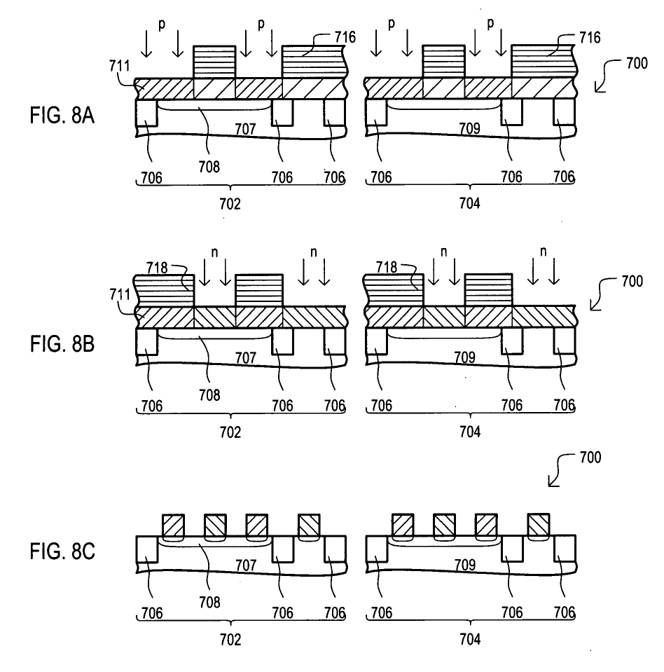

Referring now to FIGS. 7A to 8C, methods of forming four terminal integrated circuit device structures that can serve as either a JFET or a BJT are illustrated in a series of side cross sectional views.

Referring now to FIG. 7A, an integrated circuit device 700 can include a substrate having a first portion 702 and a second portion 704. Isolation structures 706 can be formed within first and second portions (702 and 704) to create active areas for the formation of either JFET or BJT devices. In one very particular arrangement, isolation structures can be formed with shallow trench isolation (STI) techniques. Optionally, a first portion 702 can be subject to a JFET well formation step, such as an ion implantation step. In FIGS. 7A to 8C, a JFET can be a p-channel JFET. Accordingly, a well formation step can create an n-type well 707. At the same, time a second portion 704 can be masked with an implant mask 708.

Referring now to FIG. 7B, a method can optionally include a collector formation step within the second portion 704. Such a step can be included to provide a different doping profile for a BJT collector versus that for a JFET well, and can be an ion implantation step. During such a step, a first portion 702 can be masked with an implant mask 710. In FIGS. 7A to 8C, a BJT can be an npn BJT. Accordingly, a collector formation step can create an n-type collector 709.

Referring now to FIG. 7C, a first portion 702 can be subject to a JFET channel formation step, such as another ion implantation step. A channel mask 712 can provide an opening at locations where a JFET channel is to be formed. A channel impurity can be opposite to that of a well impurity, and thus can create a p-type channel 708 in the example of FIG. 7C. At the same, time a second portion 704 can be masked with channel mask 712.

Referring now to FIG. 7D, a second portion 704 can be subject to a BJT base formation step, such as another ion implantation step. A base mask 714 can provide an opening at locations where a BJT base is to be formed. A channel impurity can be opposite to that of a collector impurity, and thus the formed base 716 is p-type. A first portion 702 can be masked with base mask 714.

In alternate embodiments, an impurity creation step can follow the formation of a channel and/or base, to form JFET source/drain or gate regions in a substrate, or BJT emitter and collector regions in the same substrate. Such regions can make physical contact with subsequently formed surface electrodes, as will be described below.

Referring now to FIG. 7E, a semiconductor electrode material 711 can be formed over first and second portions (702 and 704). An electrode material 711 can be a material capable of forming a pn junction with a substrate. Accordingly, in particular examples, a semiconductor material 711 can be silicon, preferably polycrystalline silicon (polysilicon), formed over and in contact with a silicon substrate including portions 702 and 704.

Referring now to FIG. 8A, first and second portions (702 and 704) can be subject to an electrode doping step. Such a step can dope portions of a semiconductor material 711 to a particular conductivity type and concentration to form certain electrodes of a JFET, BJT, or both. In the very particular example of FIG. 8A, electrodes can be doped to form source and drain electrodes of a JFET, and base electrodes of a BJT. While FIG. 8A shows base electrodes formed at the same time as source/drain electrodes, different doping steps can be used for these structures in alternate embodiments.

Referring now to FIG. 8B, first and second portions (702 and 704) can be subject to a second electrode doping step. Such a step can dope portions of a semiconductor material 711 to a different conductivity type than that of the step shown in FIG. 8A to form other electrodes of a JFET, BJT or both. In the very particular example of FIG. 8B, electrodes can be doped to form gate and well electrodes of a JFET and emitter and collector electrodes of a BJT. In alternate embodiments, an emitter and collector can be formed with different doping steps.

Referring now to FIG. 8C, first and second portions (702 and 704) can be subject to an electrode patterning step. Such a step can include etching doped semiconductor material 711 into electrode structures. Such as step can be reactive ion etch, as but one example. In addition forming a more conductive layer over all or portions of such electrodes, such as a silicide layer, could be formed prior to, or after such a patterning step. Subsequently, an integrated circuit device 700 can be subject to heat treatment step that can cause impurities to out diffuse from electrodes into a substrate below.

In this way, both JFET and BJT devices can be formed in the same substrate. Such an approach can be utilized to form bipolar devices utilized in a low voltage transmitter, low voltage repeater, and/or low voltage receiver, as described above.

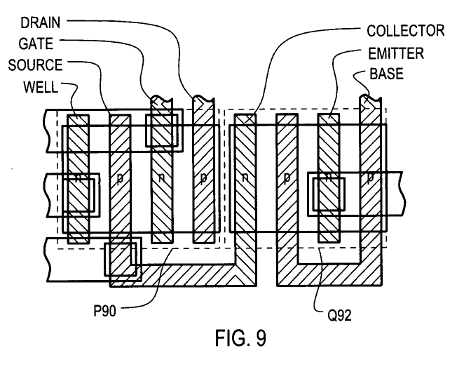

Referring now to FIG. 9, a semiconductor device having integrated JFET and BJT devices is shown in a top plan view, and designated by the general reference character 900. A semiconductor device 900 can have JFET device P90 and npn BJT Q92. A same layer(s) utilized to form electrodes can serve as a first layer of interconnect between the transistors.

It is noted that FIG. 9 shows an arrangement in which dimensions of the FET and BJT structures can be essentially the same size. However, in some embodiments it may be desirable to increase the driving capability of a BJT device. This can be advantageously done by increasing the base-emitter area of the device, which can be equivalent to increasing the channel length and/or width of a FET structure. Advantageously, such an increase in drive strength may not include a corresponding increase in channel leakage, as can be the case for IGFET type drivers.

It is understood that FIG. 9 can be a physical representation of a circuit, or a fabrication mask set, or mask data value embodied on a machine readable media.

While the above embodiments have shown devices and structures for generating low voltage swing signals in an integrated circuit, the present invention can also include systems and methods for designing such integrated circuits including such devices and structures.

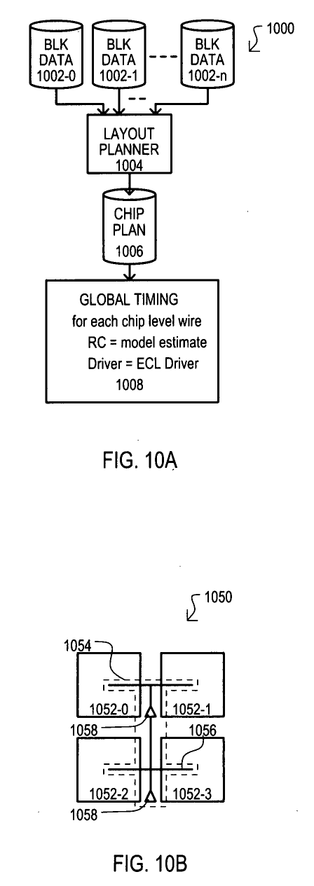

Referring now to FIG. 10A a method and system for designing an integrated circuit device is shown in a block diagram, and designated by the general reference character 1000. A system 1000 can include a number of block design databases 1002-0 to 1002-n, a layout planner 1004, a chip plan database 1006, and a global timing 1008. Block design databases (1002-0 to 1002-n) can include data for different blocks for inclusion into a single integrated circuit.

A layout planner 1004 can utilize block design databases (1002-0 to 1002-n) to generate a chip plan 1006. In particular, layout planner 1004 can arrange blocks into a single plan, including actual or estimated signal input/output positions for such blocks. Thus, a chip plan 1006 can include actual or estimated block areas and positions, along with input points for such blocks (i.e., signal, power supplies, etc.). A layout planner 1004 can also include a top level wiring plan for interconnecting blocks to one another.

A global timing 1008 can check the timing between blocks for the overall chip. However, unlike cases in which global timing can be based on models utilizing full swing drivers (e.g., CMOS or cJFET drivers), a global timing 1008 can model timing based on LV drivers, like those described above, including lower voltage swing levels.

In one particular method, a global timing 1008 can be checked against a desired value. If a global timing 1008 does not meet the value (e.g., timing, fan-out, noise immunity), a chip level timing can be adjusted. Such an adjustment can include, as but a few examples, increasing LV buffer drive strength (e.g., increasing transistor beta by implementing larger base-emitter junction area), adding LV repeaters, increasing clock line dimensions, changing clock line materials, adding FET buffering.

In this way, a system and method can have a global timing based on LV buffers rather than FET based buffers.

FIG. 10B is a timing diagram showing an integrated circuit timing model 1050 according to one embodiment. A timing model 1050 can include blocks 1052-0 to 1052-3 coupled to a global wiring network 1054. A global wiring network 1054 can include wiring legs (one of which is shown as 1056) and a number of buffer models 1058. Buffer models 1058 can be LV based buffers.

In this way, a chip design and/or simulation can have global timing (e.g., timing of signals between blocks) based on LV buffers.

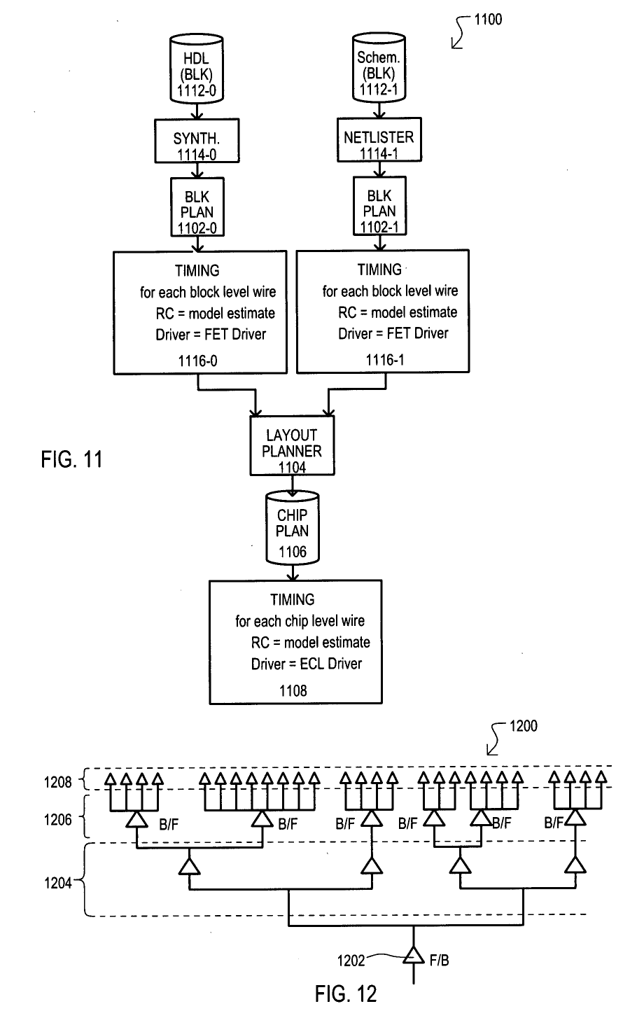

Referring now to FIG. 11, a method and system for designing an integrated circuit device according to another embodiment is shown in a block diagram, and designated by the general reference character 1100. A system 1100 can include some of the same general sections as FIG. 10A, thus like sections are referred to by the same general reference character, but with the first two digits being “11” instead of “10”.

FIG. 11 can differ from that of FIG. 10A in that a block design database 1102-0 and 1102-1 can be synthesized from a hardware design language (HDL) representation 1112-0 with a synthesizer program 1114-0. A block design database 1102-1 can also be created by a netlister program 1114-1 from a schematic design 1112-1.

In addition, a system 1100 can include a block timing 1116-0 and 1116-1 for each block design database (1102-0 and 1102-1). A block timing (1102-0 and 1102-1) can check the timing within each block. Such timing can be based on FET signal drivers, and not bipolar based drivers, such as LV buffers. Such block timing can help a layout planner 1104 optimally place signal generating points (sources) and signal reception points (sinks).

In this way, a block timing can be based in FET driver circuits, while a global timing can be based on bipolar based drivers, preferably ECL buffers like those described above.

While the various embodiments can be used for the transmission of essentially any signal between blocks of an integrated circuit, such methods and structures may preferably used to transmit a global clock signal for timing operations within and between blocks of an integrated circuit. One very particular example of such a clock arrangement is shown in FIG. 12.

Referring now to FIG. 12, a clock “tree” according to one embodiment is shown and designated by the general reference character 1200. A clock tree 1200 can include a clock source 1202, a clock distribution network 1204, conversion buffers 1206, and clock sinks 1208. A clock source 1202 can be a representation of a circuit that translates a high voltage swing signal to drive a low voltage swing signal on clock distribution network 1204. More particularly, clock source 1202 can represent a circuit that translates conventional FET level signals to BJT driven levels. Even more particularly, a clock source 1202 can be a FET to LV conversion circuit, like a global signal transmitter 202 of FIGS. 2A and 2B.

A clock distribution network 1204 can represent signal wiring for carrying a clock signal from clock source 1202 to conversion buffers 1206. For example, a clock distribution network 1204 can have resistance-capacitance models based on clock line length and/or line type. It is noted that for a differential clock source 1202 a clock distribution network can include dual signal lines.

Conversion buffers 1206 can be a representation of a circuit that translates a low voltage swing signal into a high voltage swing signal. More particularly, conversion buffers 1206 can represent circuits that translate bipolar circuit generated signals into conventional FET level signals. Even more particularly, conversion buffers 1206 can be LV to FET circuits like translator circuits (204-0 to 204-n), shown in FIGS. 2A and 2B. Conversion buffers 1206 can drive clock sinks 1208.

Of course, a clock distribution network 1204 can include LV clock repeater models in addition to wiring models.

In this way, clock trees can be designed and simulated that include clock sources that receive a FET based input signals, convert such signals for LV based drivers for transmission throughout the majority of the clock tree 1200, and then convert such signals from that of LV based drivers back to FET based driver levels.

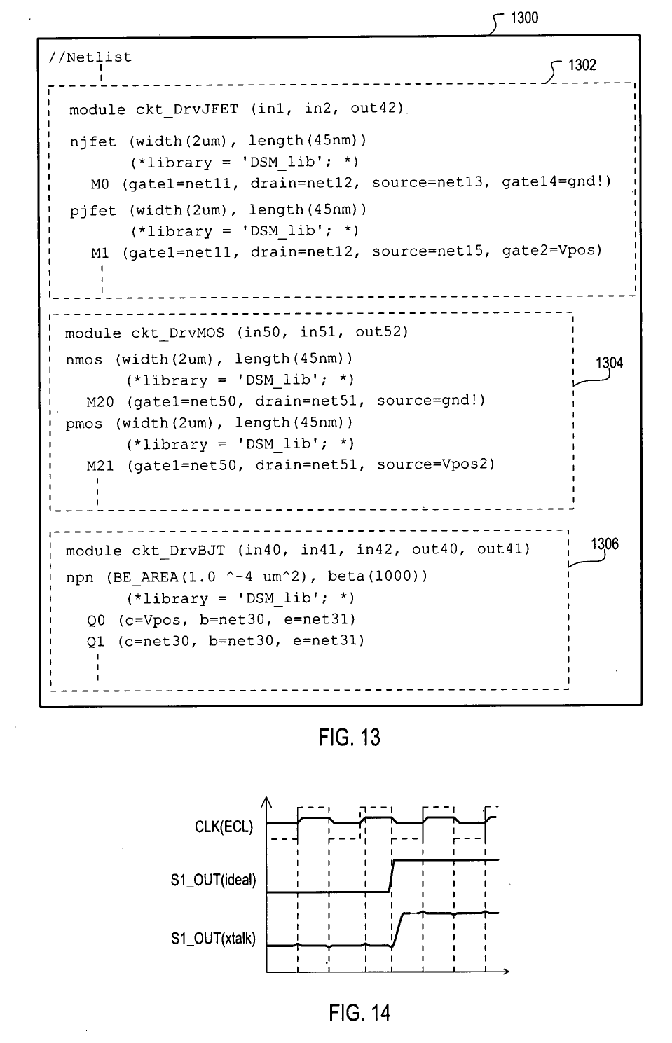

While the present invention can include integrated circuits, devices, systems and methods. the invention may also include designs embodied on machine readable media. One such example is shown in FIG. 13.

Referring now to FIG. 13, a design according to one particular embodiment is shown as a netlist in text form and designated by the general reference character 1300. A design 1300 can include declarations of element types and associated interconnections arranged into modules.

In the particular example shown, a design 1300 can include a JFET driver module “ckt_DrvJFET” 1302 and a BJT driver module “ckt_DrvBJT” 1306. Optionally, a design 1300 can include an IGFET driver module “ckt_DrvMOS” 1304. A JFET driver module 1302 can include JFET devices interconnected to drive an output node (out42) between power supply levels (Vpos and gnd!). Thus, a JFET driver module 1302 can output a relatively large voltage swing signal. In one arrangement, a JFET driver module 1302 can have a structure like that shown in FIG. 3B.

A BJT driver module “ckt_DrvBJT” 1306 can include BJT devices interconnected to drive an output node (out41) at a lower voltage swing level. In one arrangement, a BJT driver module 1306 can have a structure like that shown in any of FIGS. 4A to 4C.

The particular example of FIG. 13 also includes the incorporation of IGFET (e.g., MOS) type transistors into the same integrated circuit. Consequently, the design 1300 can include IGFET driver module “ckt_DrvMOS” 1304. An IGFET driver module 1304 can include IGFET devices interconnected to drive an output node (out52) between higher power supply levels (Vpos2 and gnd!). Thus, an IGFET driver module 1304 can output a large voltage swing signal.

It is understood that JFET devices and BJT devices declared in FIG. 13 can correspond all or in part to elements like those shown in FIGS. 7A to 7C and/or 8A to 8C.

In this way, a design can include large voltage swing based modules, such as modules with active elements only composed of FET devices, with selected nodes being driven at lower voltage swing levels and translated from such lower swing levels into higher swing levels by modules with active elements composed of BJT devices.

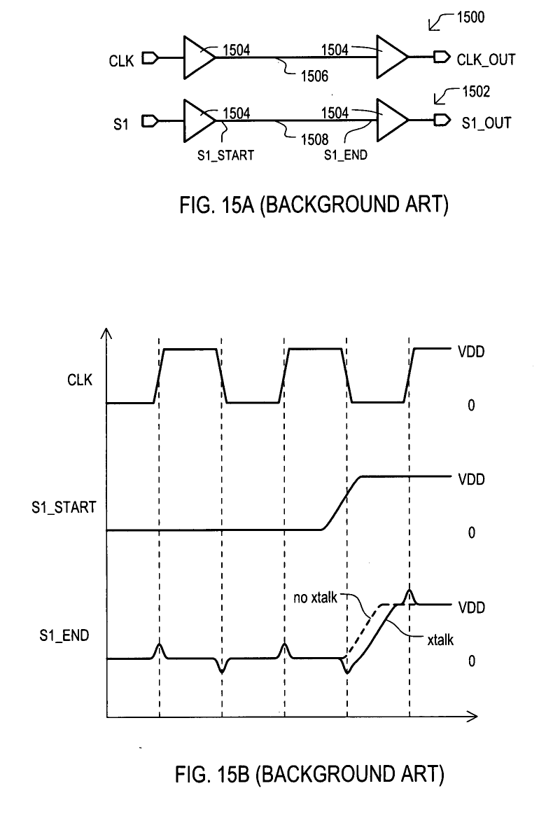

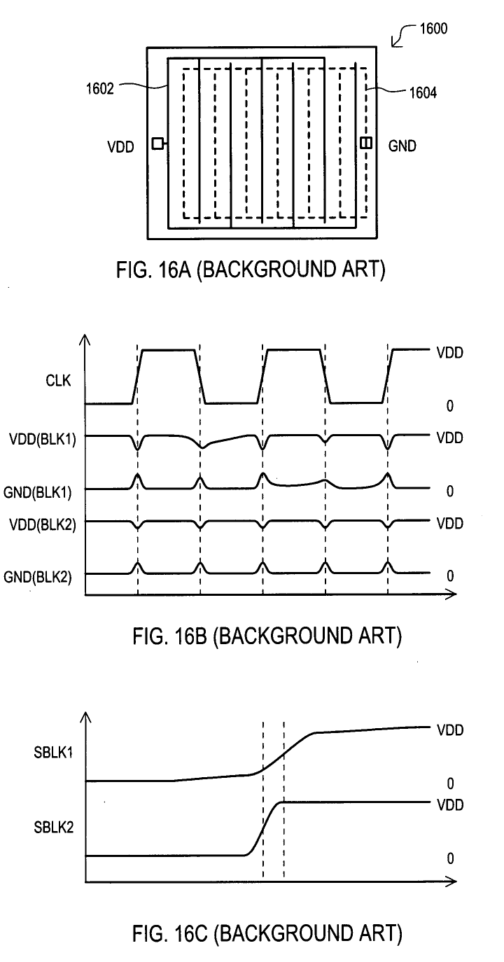

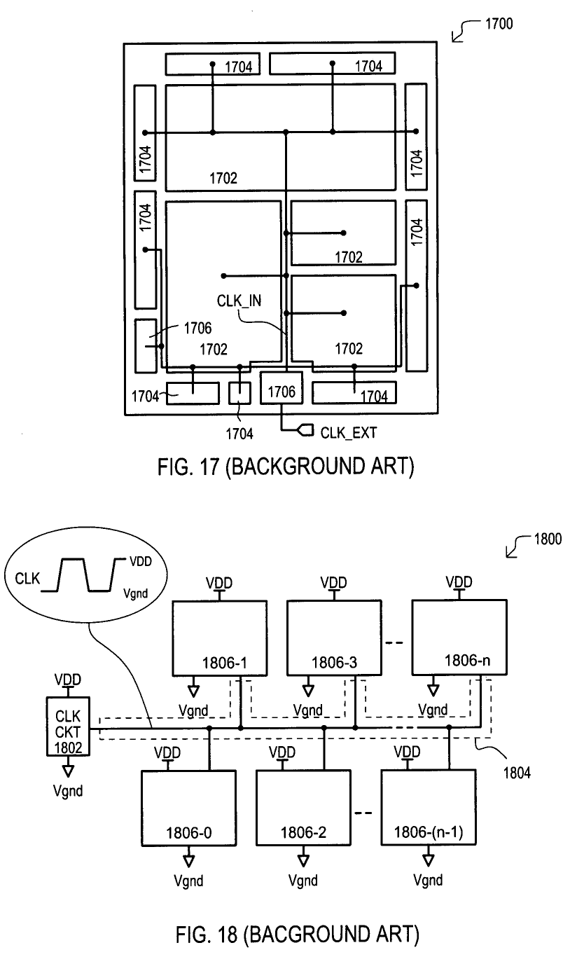

Referring now to FIG. 14, a timing diagram is shown that can be compared to the conventional response represented by FIG. 15B. FIG. 14 shows waveforms corresponding to a clock signal CLK(ECL) that can be transmitted according to any of the various embodiments shown above. Superimposed onto the signal CLK(ECL) can be a conventional high voltage swing clock signal, shown by a dashed line waveform. Waveform S1_OUT (ideal) can be an ideal output signal from signal path. That is, S1_OUT can be a desired result. Waveform S1_OUT(xtlk) can represent an output signal resulting from unwanted crosstalk, but with the reduced voltage swing of signal CLK(ECL).

As shown, because signal CLK(ECL) has a lower voltage swing, a resulting impact of crosstalk on signal S1_OUT(xtlk) can be reduced over conventional approaches.

In this way, adverse effects of capacitive coupling can be reduced utilizing signaling according to the various embodiments. It is also noted that such reductions in parasitic rising and falling of a signal can be particularly advantageous in JFET based integrated circuits, which seek to avoid uncontrolled voltage spikes that can forward bias p-n junctions within such JFET devices.

Still further, by including ECL related buffers to generate lower voltage swing signals, an input impedance and/or signal reflections can be reduced as compared to a FET based driver circuits.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is, an inventive feature of the invention may include an elimination of an element.

While various particular embodiments set forth herein have been described in detail, the present invention could be subject to various changes, substitutions, and alterations without departing from the spirit and scope of the invention.

What is claimed is:

1. An integrated circuit device, comprising:
a plurality of circuit blocks, each circuit block comprising field effect transistors formed in a common substrate that execute at least one function in response to an input timing signal that varies within a first voltage range;
a translator circuit corresponding to each circuit block that generates the input timing signal for the circuit block in response to at least one chip timing signal that varies within a second voltage range that is no more than half the first voltage range, each translator circuit comprising a plurality of bipolar junction transistors (BJTs) formed in the common substrate, each BJT having a base electrode, collector electrode, and emitter electrode comprising at least one deposited semiconductor layer formed on the surface of the substrate;
a chip timing circuit formed in the common substrate that generates the at least one chip timing signal; and
a signal distribution wiring that couples the chip timing signal to the translator circuits.

2. The integrated circuit device of claim 1, wherein:
at least one of the circuit blocks comprises active circuit devices, the active circuit devices consisting of field effect transistors (FETs).

3. The integrated circuit device of claim 2, wherein:
the FETs comprise insulated gate field effect transistors (IGFETs).

4. The integrated circuit device of claim 3, wherein:
the first voltage range is no more than about one volt.

5. The integrated circuit device of claim 2, wherein:
the FETs comprise junction field effect transistors (JFETs).

6. The integrated circuit device of claim 5, wherein:
the first voltage range is no more than about 0.7 volts.

7. The integrated circuit device of claim 1, wherein:
each translator circuit comprises a differential pair of BJTs having commonly connected emitters, the base of a first of the differential BJTs being coupled to receive the at least one chip timing signal.

8. The integrated circuit device of claim 7, wherein:
at least one chip timing signal comprises complementary chip timing signals that each vary within the second voltage range; and
each translator circuit comprises a first of the differential BJTs coupled to receive one of the complementary chip timing signal, the base of the second differential BJT being coupled to receive the other of the complementary chip timing signals.

9. The integrated circuit device of claim 7, wherein:
each translator circuit further includes an output BJT having a base coupled to a collector of one of the differential BJTs, a collector coupled to a power supply node, and an emitter that provides the input timing signal to the corresponding circuit block.

10. The integrated circuit device of claim 9, wherein:
each translator circuit further includes a local buffer circuit having active circuit devices consisting of FETs, an input of the local buffer circuit being coupled to the emitter of the output BJT.

11. The integrated circuit device of claim 10, wherein:
the translator circuit FETs include a buffer FET of a first conductivity type having a gate coupled to the emitter of the output BJT, and the output BJT has a collector coupled to the power supply node.

12. The integrated circuit device of claim 1, wherein:
the chip timing circuit comprising
a differential pair of timing BJTs having commonly connected emitters, a base of a first of the differential timing BJTs being coupled to receive a reference voltage within the first voltage range, a base of the second differential timing BJT being coupled to receive an input timing signal that varies within the first voltage range, and
at least a first driver BJT having a base coupled to a collector of a first of the differential timing BJTs, a collector coupled to a power supply node, and an emitter that provides the at least one chip timing signal.

13. The integrated circuit device of claim 12, wherein:
at least one chip timing signal comprises complementary chip timing signals that each vary within the second voltage range; and
the chip timing circuit further includes
that first driver BJT provides a first of the complementary chip timing signals at its emitter, and
a second driver BJT having a base coupled to a collector of a second of the differential timing BJTs, a collector coupled to the power supply node, and an emitter that provides a second of the complementary chip timing signals at its emitter.

14. The integrated circuit device of claim 1, wherein:
the signal distribution wiring comprises at least one metallization layer that includes at least one wiring line coupled between the chip timing circuit and each translator circuit.

15. The integrated circuit device of claim 14, wherein:
at least one chip timing signal comprises complementary chip timing signals that each vary within the second voltage range; and
the signal distribution wiring comprises at least two wiring lines coupled between the chip timing circuit and each translator circuit.

16. The integrated circuit device of claim 1, further including:
an input clock circuit that generates a periodic internal clock signal that varies within the first voltage range; and
the chip timing circuit generates the at least one chip timing signal in response to the internal clock signal.

17. The integrated circuit device of claim 1, further including:
the input clock circuit comprises a buffer circuit having active circuit devices consisting of FETs.

18. The integrated circuit device of claim 1, wherein:
the input clock circuit is coupled to receive an external clock signal generated externally to the integrated circuit device.

19. The integrated circuit device of claim 1, wherein:
each circuit block comprises junction field effect transistors (JFETs), each JFET having a gate electrode, source electrode, and drain electrode, the electrodes comprising the at least one deposited semiconductor layer formed on the surface of the substrate.

20. A computer readable medium including at least a portion of an integrated circuit design, comprising:
a plurality of section data structures defined as operating between a high power supply voltage and a low power supply voltage, each section defined as having a local timing signal node;
a translator data structure corresponding to each section defined as receiving at least one global timing signal and having an output connected to the corresponding local timing signal node; and
a global driver data structure defined as operating between the high power supply voltage and a second low power supply voltage, and generating the least one global timing signal to vary between a reference voltage and a first signal voltage, the difference between the first signal voltage and the reference voltage being no more than about one fifth the difference between the low power supply voltage and the high power supply voltage.

21. The computer readable medium of claim 20, wherein:
the section data structures are defined as consuming power based on at least the switching of complementary field effect transistors (FETs); and
each translator data structure is defined as consuming power based on at least the switching of bipolar junction transistors (BJTs).

22. The computer readable medium of claim 20, further including:
a wiring data structure, including global wiring segments defined as connecting the at least one global timing signal to the translator data structures, and local wiring segments defined as interconnecting circuit components of each section data structure.

23. The computer readable medium of claim 22, wherein:
the global driver data structure is defined as generating differential global timing signals, a first differential global timing signal varying between the reference voltage and the first signal voltage, and a second differential global timing signal that varies between the reference voltage and a second signal voltage, the first signal voltage being greater than the reference voltage, the second signal being less than the reference voltage by no more than about one fifth the difference between the low power supply voltage and the high power supply voltage.

24. The computer readable medium of claim 20, wherein:
each translator data structure is defined as including bipolar junction transistor (BJT) models including a differential pair of BJT models having commonly connected emitters, and at least one driver BJT model having a collector connected to a high power supply node, a base connected to a collector of one of the differential BJT models, and an emitter that provides the at least one signal voltage.

25. The computer readable medium of claim 20, wherein:
each global driver data structure is defined as including bipolar junction transistor (BJT) models including a differential pair of BJT models having commonly connected emitters, and at least one driver BJT model having a collector connected to a high power supply node, a base connected to a collector of one of the differential BJT models, and an emitter that provides the at least one signal voltage.

26. The computer readable medium of claim 20, wherein:
at least one of the section data structures includes
at least a first net that describes connections between circuit elements including a plurality of JFETs of a first conductivity type and a plurality of JFETs of a second conductivity type.

27. The computer readable medium of claim 20, wherein:
at least one of the section data structures includes representations of parallel semiconductor lines forming gate, source and drain terminals of junction field effect transistors (FETs); and
each translator data structure includes representations of parallel semiconductor lines forming at least the base and emitters of at least two bipolar junction field effect transistors (BJTs).

28. An integrated circuit design method, comprising the steps of:
for each of a plurality of blocks, generating local timing values based on field effect transistor (FET) switching originating from a signal sink for the block and transmitted over a local wiring network of the block; and
for an integrated circuit (IC) containing the blocks, generating a global timing value based on global low voltage transistor switching originating from at least a first signal source point and transmitted over a global wiring network to each of the blocks, and local bipolar transistor (BJT) switching corresponding to each signal sink; wherein
the FET switching transitioning between values of a first range, and the global low voltage switching transitioning between values of a second range that is less than the first range.

29. The method of claim 28, wherein:
the first range is between essentially a high power supply voltage and a low power supply voltage, the second range is between a bias voltage and a voltage offset from the bias voltage.

30. The method of claim 28, wherein:
the global low voltage switching includes complementary switching that generates a first signal and a second signal, the first signal varying between the bias voltage and a positive offset voltage from the bias voltage, the second signal varying between the bias voltage and a negative offset voltage from the bias voltage.

31. The method of claim 28, wherein:
the global low voltage switching corresponds to an emitter-coupled logic (ECL) circuit having a differential pair of BJTs with commonly connected emitters, and at least one driver BJT having a collector coupled to a high power supply, a base coupled to a collector of one the differential pair BJTs, and an emitter that outputs to the global timing network.

32. The method of claim 31, wherein:
generating the local timing values further includes adding a translator timing at the signal sink based on the local BJT switching.

33. The method of claim 32, wherein:
the local BJT switching corresponds to an emitter-coupled logic (ECL) circuit having a differential pair of BJTs with commonly connected emitters, and at least one driver BJT having a collector coupled to a high power supply, a base coupled to a collector of one the differential pair BJTs, and an emitter that outputs to the local timing network.

34. The method of claim 28, further including:
generating an overall timing value for the IC based on both the local timing and the global timing; and
if a portion of the overall timing is outside of a desired limit, modifying the low voltage switching to alter the global timing value.

35. The method of claim 34, wherein:
the global low voltage switching is a global BJT switching, and modifying the low voltage switching includes modifications selected from the group consisting of:
determining global BJT switching on a larger base-emitter junction area than initial BJT switching,
adding additional global BJT switching in a signal path as a signal repeater, and
changing the global BJT switching from generating a single ended signal to generating complementary signals.
